(19) United States
(12) Patent Application Publication
(10) Pub. No.: US 2004/0193982 A1
(43) Pub. Date: Sep. 30, 2004

(54) Built-in self-test for digital transmitters

(75) Inventors: Veerendra Bhora, Sunnyvale, CA (US); Tibor Boros, San Francisco, CA (US); Pulakesh Roy, Sunnyvale, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: ArrayComm, Inc.

(21) Appl. No.: 10/404,794

(22) Filed: Mar. 31, 2003

(51) Int. Cl. G01R 31/28

(52) U.S. Cl. 714/726

(57) ABSTRACT

The present invention allows a complex digital processing engine to be tested automatically and autonomously using a minimum of memory and processing resources. In one embodiment, the invention includes an input buffer to store a digital test sequence, a digital data modulator coupled to the input buffer to generate a modulated digital sample sequence using the test sequence, a test buffer coupled to the modulator to receive and store a representation of the sample sequence, and a test buffer output to enable the test buffer contents to be compared to a reference sequence.

### BACKGROUND OF THE INVENTION

1. Field

The present invention pertains to the field of built-in self-testing equipment for integrated circuits and in particular to a built-in self-test system for a radio modulator circuit.

2. Background of the Related Art

Integrated circuit manufacturers have integrated built-in self-test (BIST) directly into very large scale integrated circuit (VLSIC) systems such as microprocessors and memory devices. Such BIST systems have a SELF-TEST pin that can be asserted to cause the VLSIC system to run the integrated self-test and either assert or de-assert a BIST FAIL pin depending on the results.

Digital radio systems present several challenges not present in microprocessors and memory devices. A digital radio system typically includes a digital modulator either as an independent chip set or as part of a larger integrated circuit (IC) device. The modulator receives a particular input data bit stream and upsamples it for transmission. In more detail, it may encode it, apply error correction or detection codes, apply puncturing or compression, map the bits to symbols, upsample the symbols, and modulate the upsampled symbols to an intermediate frequency (IF) or spread the upsampled symbols with an appropriate spreading code. The input bit stream may be rather large to support an entire data burst and the upsampled output stream will be several times larger. This puts large demands on the amount of memory and processing power required to run the test and check the accuracy of the result. Such demands are not present with microprocessors and memory devices.

A further challenge is that testing is typically required not only for design verification and quality assurance but also in the field. Unlike many microprocessors and memory modules, radio modulators are often subjected to extreme environmental conditions. Factors such as temperature, humidity, power supply voltage, clock signal quality etc. can affect the accuracy of the modulator or cause malfunctions. Field testing confirms that the modulator continues to operate through environmental changes and over time.

For digital radio modulator modules, testing is typically performed using external test equipment. The test equipment loads a predetermined test sequence to an input RAM (random access memory), launches the modulator to be tested, and captures the modulator's output data. The output data is processed by a logic analyzer and then compared to reference data to determine whether the transmission from the modulator module was correct.

The external test equipment is necessarily expensive. For high-speed digital modulators, the logic analyzer must have enough capacity to capture at least an entire burst. While the input data stream may be manageable, the encoded, upsampled data stream will be much larger. In addition, it is difficult to perform such testing in the field. To connect the external equipment, a technician must visit the radio site, take the modulator off-line, open up housings and access specially provided access ports. Further, the testing can be time-consuming. If the modulator has several different modes or encoding or modulation schemes, then each one and each variation may require testing. For each test, the large output bit stream must be compared to the reference data.

### SUMMARY

The present invention allows a complex digital processing engine to be tested automatically and autonomously using a minimum of memory and processing resources. In one embodiment, the invention includes an input buffer to store a digital test sequence, a digital data modulator coupled to the input buffer to generate a modulated digital sample sequence using the test sequence, a test buffer coupled to the modulator to receive and store a representation of the sample sequence, and a test buffer output to enable the test buffer contents to be compared to a reference sequence.

### BRIEF DESCRIPTION OF THE DRAWINGS

The present invention is illustrated by way of example, and not by way of limitation, in the Figures of the accompanying drawings in which like reference numerals refer to similar elements and in which:

FIG. 1 is a functional block diagram of radio communication system incorporating a built-in self-test according to one embodiment of the invention;

FIG. 2 is a functional block diagram of radio communication system incorporating a built-in self-test according to a second embodiment of the invention;

FIG. 3 is a functional block diagram of Cyclic Redundancy Code generator suitable for use with the invention;

FIG. 4 is a functional block diagram of radio communication system incorporating a built-in self-test according to a third embodiment of the invention; and

FIG. 5 is a block diagram of a computer adapter card incorporating an embodiment of the present invention can be implemented.

### DETAILED DESCRIPTION OF THE INVENTION

The present invention provides a built-in self-test for a digital radio modulator or other device. The test can be managed by a master control unit (MCU) or by a controller in the physical layer processor. Using a cyclic or recursive algorithm, such as a linear feedback shift register (LFSR) to process the modulator output, the gate count for the self-test functionality can be kept extremely low and no extra input and output RAMs are required. Using a test controller, a reference value register and a comparator, a test or a series of tests can be run autonomously without interfering with higher layer processes.

### First Example Embodiment of the BIST

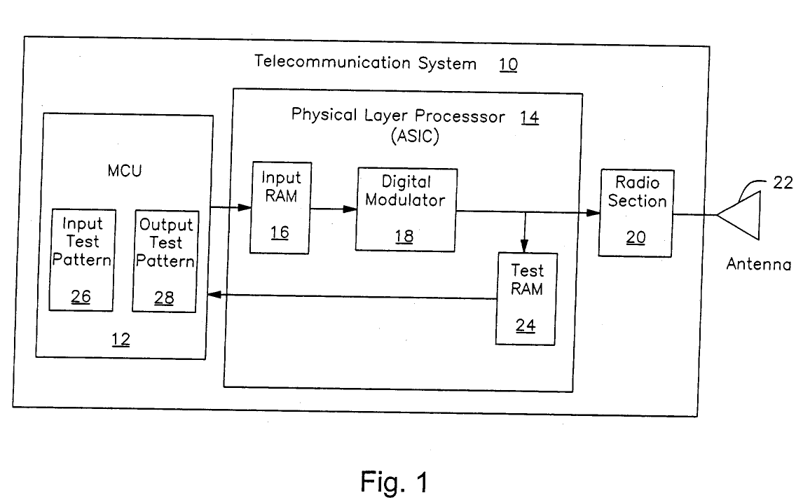

Referring to FIG. 1, a radio system 10 is shown in a simplified block diagram form. The radio system 10 includes a master control unit (MCU) 12 which interfaces to higher layer processes and to a physical layer processor 14 such as an application specific integrated circuit (ASIC) 14. The MCU may provide connectivity to local area or wide area networks or to a node of such a system. In one embodiment, the radio system can be integrated into a computer system so that the MCU connects through the computer system bus. This can be done in any of a variety of different ways including a PCMCIA (Personal Computer Memory International Association) interface, SD (Secure Digital) card interface, or MultiMedia card interface, USB (Universal Serial Bus) among others.

The ASIC 14 is coupled to the MCU and includes an input RAM or input buffer 16 that receives data bits from the higher layers for transmission using the radio system as well as a digital modulator 18 that performs the baseband processing on the data bits to be transmitted. The input RAM is coupled to the digital modulator to supply the transmit bit stream to the modulator. The modulator can perform any of a variety of different functions, such as encoding, puncturing, compressing, error detection or correction coding, modulating, mapping into a symbol translation scheme, upsampling, and more depending on the particular air interface through which the data is to be transmitted. In one embodiment, the digital modulator encodes the data, calculates and appends cyclic redundancy check codes, modulates the bits into QPSK (Quaternary Phase Shift Keying) symbols or QAM (Quadrature Amplitude Modulation) symbols and upsamples the symbols and upconverts from baseband to an intermediate frequency(IF). The resulting output bits are a sequence of words to be applied to a digital to analog converter of the radio section.

The radio section 20 converts the upsampled symbols to an analog waveform modulates the waveform at the assigned carrier radio frequency (RF) according to the selected modulation scheme and transmits the analog waveform to a connected antenna 22. The radio system will typically contain other components depending upon the particular implementation and application. These components are not illustrated in order not to obscure the more important features of the invention.

The physical layer processor also includes a test RAM 24 coupled to the output of the digital modulator between the modulator and the radio section. The test RAM is coupled to the MCU as well. The MCU further contains an input test pattern memory 26 and an output reference buffer 28. These are accessible to the MCU for performing built-in self-test (BIST) functions and can either be integrated with the MCU or provided as separate components. Similarly, the test RAM can be integrated with the physical layer processor, with the MCU or provided as a separate component.

In the example of FIG. 1, the MCU initiates the BIST by reading a test pattern from the test pattern memory. Alternatively, the test pattern can be generated using an appropriate instruction sequence. The instruction sequence can cause the MCU to generate a test pattern or to activate some other test pattern generator. The MCU can initiate the pattern based on timing or a clock, or based on an external request received from higher layer processes. The test pattern, however produced, is provided by the MCU to the input RAM of the physical layer processor. From there it is read and processed by the digital modulator according to the modulation code and sequence to be tested. If there is only one mode, then that mode is used. If the digital modulator has several modes, then the MCU can instruct the digital modulator which mode to apply using control lines (not shown). Alternatively, the MCU can detect the current mode of the digital modulator and opportunistically apply a test pattern to achieve the desired test when the desired mode is engaged.

The digital modulator's upsampled output sequence to the radio section is detected by the test RAM 24 and stored there for later analysis. The MCU can disable the radio section to prevent the test pattern from being transmitted using control lines (not shown). This may reduce system interference for other radio systems. The test RAM stored bit stream is made accessible to the MCU where it can be compared to the output reference buffer. The output reference buffer provides a reference value that can be compared to the upsampled output sequence generated by the modulator. The results of the comparison determine whether the input test pattern has been properly modulated by the digital modulator. The MCU after the test can generate a flag, such as a BISTFAIL flag or a SUCCESS/FAIL flag, as appropriate, to indicate the status of the digital modulator to higher layer processes.

### Second Example of the BIST

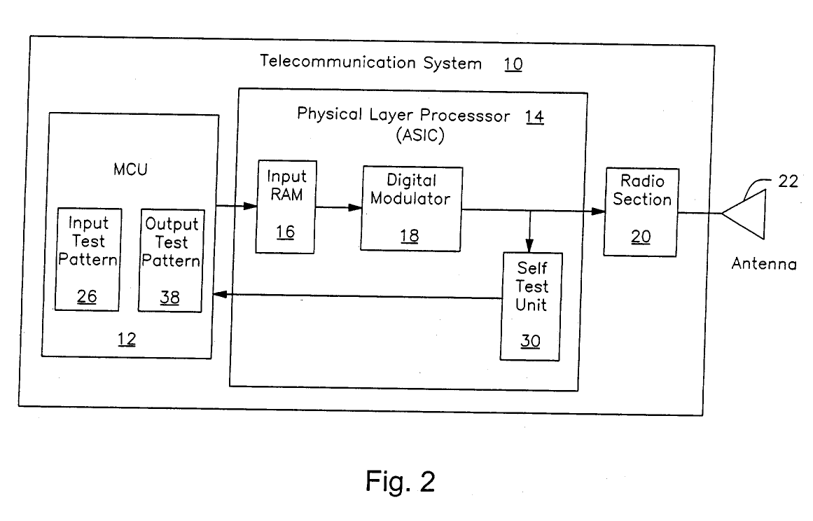

The example of FIG. 2 shows a radio system that requires much fewer resources. As with FIG. 1, the radio system 10 of FIG. 2 includes the MCU 12 connected to the physical layer processor 14 connected to the radio section 20 connected to the antenna 22. The physical layer processor connects to the MCU through an input RAM 16 and a digital modulator 18. As in FIG. 1, the MCU includes a test pattern memory 26 with one or more input test patterns and an output reference buffer 38 with a corresponding set of reference values for test output sequences. However, the reference values are different from those of FIG. 1, as described in more detail below.

In the example of FIG. 1, both the test RAM 24 and the output test pattern memory 28 may be required to be very large. If, for example, the transmit rate is 18 Megasamples per second, the transmitted samples are 10 bits wide and a transmit burst is 545 microseconds long, then the output for a single burst would be 98100 bits. Not only must the test RAM contain the entire sequence but the output reference value buffer must contain the same sequence. In addition, a comparator must compare the 98100 bits of the test RAM with the 98100 bits of the reference memory. If there are several different transmission, modulation or encoding modes, then these output reference value buffers may need to be duplicated for each mode.

By contrast, due to the encoding and upsampling, the input test pattern can be much smaller. Encoding can double the number of bits and upsampling can multiply the number of bits by 18 or 36 or more, depending, in part, on the speed of the digital to analog converter of the radio section. In one embodiment, the input bit stream is between 100 and 1000 bits, depending on the modulation scheme employed, while the output is 98100 bits. An input bit stream of 100 to 1000 bits requires much less memory than the upsampled output sequence. To save more resources on the ASIC the 100 bit sequence can be used with 10 repetitions as the 1000 bit input sequence. Alternatively, the input bit sequence can be generated, using e.g. a pseudorandom number generator or some other simple algorithm and not stored in memory.

In the example shown in FIG. 2, the amount of memory required for the upsampled output sequence is reduced by replacing the test RAM 24 with a self-test unit 30. The self-test unit receives all of the bits produced by the digital modulator, however, instead of storing all of the bits, it compresses them. The very large number of bits is reduced to a very small number using a simple process that does not require much processing time. While the compression can occur at any time before the comparison, the self-test unit is simplified if the entire e.g. 98100 bits is not stored. By compressing the output bit stream, the memory requirements can be reduced and the comparison can be made much more quickly.

In one example, the 98100 bits is reduced in the self-test unit to 16 bits using a linear recursive algorithm that operates on the bits as they are received. A variety of different compression algorithms of both block and recursive types can be used. Such compression algorithms include Lempel-Ziv algorithms, Walsh-Hadamard codes, and various transforms such as discrete wavelet transforms (DWT) and other Fourier transform based compression algorithm.

As an alternative, the self-test unit can use error detection or correction algorithms, such as Hamming codes, Reed-Solomon codes, BCH codes and others. One design consideration is the complexity of the calculations required to perform the compression. Another design consideration is the amount of information that is desired about the errors in the output bit stream. A cyclic redundancy check algorithm is particularly well-suited to many applications because it can accurately represent whether errors are present using very few detection bits. In other words, if an error exist, then a fail is very likely to be indicated. If simple parity were to be used, for example, some errors will cancel out other errors. This makes the test less accurate.

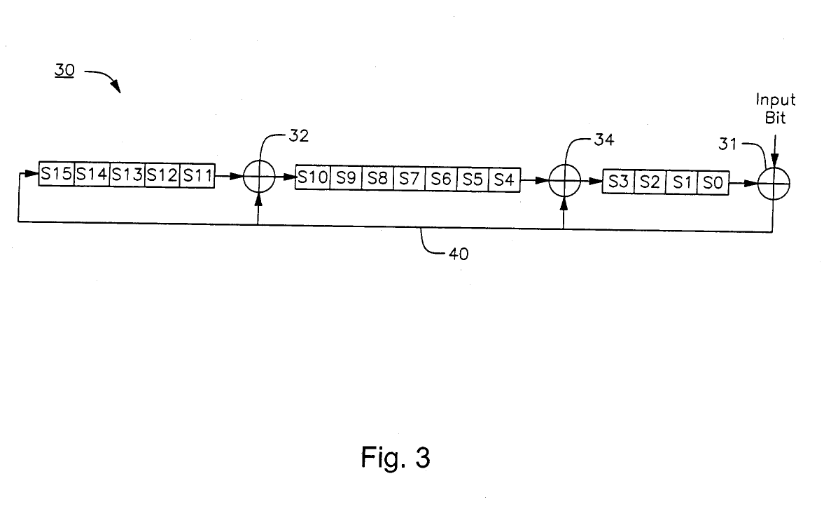

Another advantage of cyclic redundancy codes is that they can be calculated using a simple linear feedback shift register (LFSR). Such a LFSR is shown in a diagrammatic form in FIG. 3. This LFSR is one embodiment of the self-test unit 30 of FIG. 2. The LFSR of FIG. 3 can take an input bit stream of any length and convert it to sixteen bits. It is made up of a sequence of shift registers S0 to S15 and appropriately spaced adders 32, 34, 36.

In operation, the input bits are received from the digital modulator 18. They are supplied to the third adder 31. The third adder results are sent on a feedback line 40, to the second 34 and first 32 adders as well as to the first shift register S15. The bits cycle through the first five shift registers S15 to S11 to the first adder which adds the result of register S11 to the bit from the feedback line. The result goes to the next shift register S10. The bits then cycle through the next seven shift registers S10 to S4 to the second adder 34 which adds the result to the feedback line bit and provides the result to the next shift register S3. The bits are cycled through the remaining four shift registers S3 to S0 and then to the third adder 31 which adds the S0 value with the input bit and, as mentioned above, cycles the result back to the first shift register S15. This hardware implements the generating polynomial g(x)=x¹⁶+x¹²+x⁵+1. While the particular LFSR configuration described and shown is believed to be a good choice in many applications, many other configurations or generator polynomials can be applied. Higher accuracy can be obtained using a more complex algorithm, e.g. a 32-bit LFSR. However, there are also additional costs.

A LFSR due to its cyclic and recursive nature is well suited to situations in which the output bit stream can vary in length. The output bit stream might vary in length because of different transmission modes. For example, if a QPSK transmission mode might produce more bits than a BPSK (binary phase shift keying) transmission. The output bit streams might also differ in length due to differences in message formats. A burst containing a traffic channel (TCH) message might have more bits than a registration overhead burst or a paging burst.

Returning to FIG. 2, the self-test unit 30 receives the output bit stream from the digital modulator 18, applies the generator polynomial as the bits are received and within a few clock cycles of the end of the output bit stream, has produced its final compressed error detection code result. A block code can also be used with appropriate compensations for longer delays. The MCU can then read out the 16 bit value in the LFSR of the self-test unit and compare it to the 16 bit reference value 38 that it has stored in memory. Such a comparison takes very little hardware, very little bus communications bandwidth and very little processing resources compared to comparing the results of an entire 98100 bit output stream. In addition, it can be applied to output blocks of different sizes with no change in any of the hardware or process. Only the value in the output test pattern reference memory 38 needs to be changed.

### Third Example Embodiment of the BIST

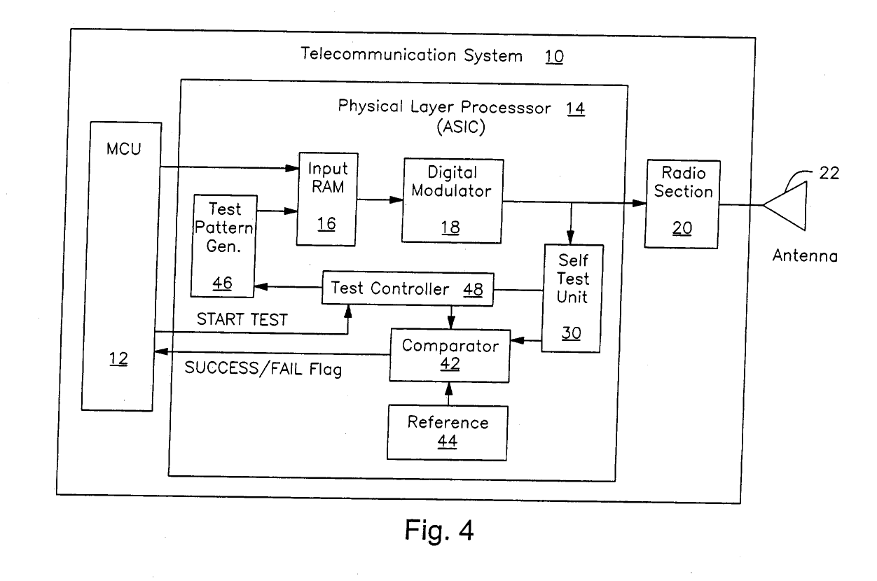

FIG. 4 shows an alternative configuration for the BIST architecture of the present invention. In FIG. 4, almost all of the BIST functions are contained within the physical layer processor 14, thereby freeing MCU resources for other functions and processes. In FIG. 4, the radio system 10 includes an MCU 12, physical layer processor 14, such as an ASIC and a radio section 20 coupled to an antenna 22. The ASIC includes an input RAM 16 for the bit stream that is to be transmitted and a digital modulator 18 to perform the baseband processing needed for the radio section to send the signal.

The MCU, in addition to its connection to the input RAM, communicates with the ASIC through a STARTTEST line and a SUCCESS/FAIL flag line. These can be the same or two different lines and can be multiplexed with other control lines if desired. In alternative architectures, the STARTTEST and SUCCESS/FAIL signals can be coupled to some other component of the radio system so that the MCU is not a part of the BIST operation. Using these two lines, the physical layer processor performs its BIST operations autonomously. In some embodiments, it is preferred that the BIST process be controlled by the MCU, so that the MCU can determine the modulator mode and select the time of the test so that it does not interfere with normal transmissions of the radio system. In addition, the MCU can disable the radio section or any other components so as to reduce the impact of the test on normal operation of the system.

The physical layer processor in this embodiment has been augmented with a self-test unit 30, such as a LFSR similar to the one of FIGS. 2 and 3. The self-test unit is coupled to a comparator 42 that can compare the values in the LFSR to the values in a reference register 44. A test pattern generator 46 provides a test pattern that corresponds to the reference register value for the particular transmission mode. The test pattern generator can be a register with a stored reference value or it can generate the test pattern each time. In order to reduce the hardware resources required, the test pattern generator can be implemented using a conventional pseudorandom number (PN) sequence generator of any of a variety of different types. This may be particularly suitable where the input buffer is very large.

The physical layer processor also includes a BIST controller 48. In the illustrated example, the BIST controller receives the STARTTEST signal from the MCU. The BIST controller then triggers the test pattern generator to fill the input RAM 16. This bit stream is encoded and modulated by the digital modulator in accordance with the mode that has been invoked by the MCU. The self-test unit 30 receives the bit stream generated by the digital modulator and applies its generator polynomial. At the appropriate time, the BIST controller commands the comparator 42 to read out the self-test unit value and compare it to the output test pattern stored in the reference register 44. In the illustrated example, the test results, positive or negative, are indicated on the SUCCESS/FAIL line to the MCU. Alternatively, the comparator can indicate the results to the test controller which can relay or interpret the results for transmission to the MCU. During this process the radio section may be disabled.

As an alternative to the LFSR suggested in FIG. 4, the output sequence can be compressed or reduced in any of the other ways mentioned above. As a further alternative, the entire output sequence can be stored and compared to a reference output test pattern. While this may consume considerable hardware resources on the physical layer processor, it will not interfere with any operations of the MCU. In addition, communication lines can be specifically provided on the ASIC to accommodate the large sequences involved. For some operations in which the output sequence is much shorter, the output sequences may be much easer to store and compare.

As a further alternative, the BIST controller can autonomously set the transmission mode for the digital modulator. Through a separate control interface to the digital modulator, it can select a particularly common or important transmission mode or it can cycle through all or most of the transmission modes. Through its control of the input test pattern and its control of the output test pattern, all modes can be tested in sequence or as opportunities are allowed by the MCU. The test results can be combined into a single SUCCESS/FAIL flag or the results for each mode can be sent to the MCU. Using this information, the MCU can choose to disable certain defective modes until test results are returned positive. Such a situation could arise from adverse temperature conditions. A particularly complex mode may not operate accurately in adverse temperatures while a simple mode may continue to work. When the temperature returns to normal, all modes may become functional.

The described embodiments can allow a comprehensive BIST to be provided with a very low gate count and very little additional RAM. External test equipment can be completely avoided and the MCU or BIST controller can ensure proper synchronization. Using a LFSR or similar compression algorithm, the output comparison can be performed very quickly with very few processing or memory resources. When a significant portion of the BIST functionality is integrated into the physical layer processor, the BIST operations can be customized to optimize the test validity for the particular processor design. This improves the test and simplifies the construction of the MCU. The MCU need only be able to supply a STARTTEST signal and receive the test result. There is no need to program the MCU with any details of the testing algorithm. The integrated autonomous BIST described above can also be applied to a great variety of different kinds of processors at the physical layer or at higher layers. It can also be applied beyond application specific IC's to general purpose or field programmable IC's.

### Card Architecture

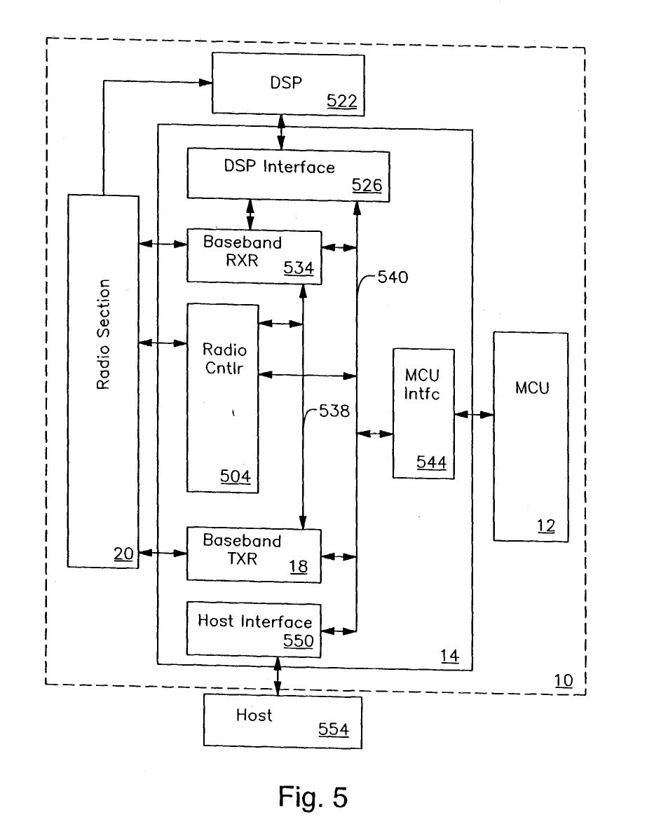

FIG. 5 is a block diagram of a removable device 10, such as a PCMCIA (Personal Computer Memory Card International Association) card, SD (Secure Digital) card, MultiMediaCard or USB (Universal Serial Bus) device, in which embodiments of the invention may can be implemented. The device is coupled with a host 554 at a port or slot. The host system can be a mobile computer (for example a laptop, notebook, or tablet PC), a desktop computer, a hand-held device (for example palmtops, PDAs, cellular phones, digital cameras), or any other data source or sink including other computers, computer peripherals, and other electronic products.

The card 10 includes the high-layer controller or master control unit (MCU) 12 to perform higher layer processing, such as layer-2, layer-3, and layer-4 processing coupled to the physical layer processor, such as an ASIC (Application Specific Integrated Circuit) 14 to perform lower layer processing, such as layer-0 and layer-1 processing through an MCU interface 544. The radio section 20 is coupled to the ASIC through a baseband receiver 534, the baseband transmitter or digital modulator 18 and radio controller 504. A DSP (digital signal processor) 522 is coupled to the ASIC through a DSP interface 526 and to the radio section to process data packets received and transmitted through the radio 20. As one example, on the uplink the MCU 12 can provide layer-2 format data to the ASIC 14 via an MCU interface 544. The ASIC processes the data to generate a modulated transmit signal that is provided to the radio section 20.

The DSP interface 526 is included in the ASIC 14 to interface data, interrupts, and control signals between the DSP and the ASIC, the baseband receiver 534 and the baseband transmitter 18. A radio controller line 538 conveys radio control signals within the ASIC, an MCU line 540 conveys controls and data from the MCU within the ASIC, and the radio controller 504 controls the components within the radio. The radio controller contains an instruction execution unit and controls power and timing for components of the radio. The ASIC also includes a PCMCIA or other type of host interface 550 to provide an interface with the PCMCIA port or slot of the host 554.

In the card 10 of FIG. 5, the ASIC 14, the radio section 20, and the DSP 522 each reside on separate chips or modules, although this is not required, and in an alternate embodiment any one or more, or all, can be combined on a common chip or module. In addition, while the interfaces and most registers described above are shown as residing on the ASIC, any one or more of these interfaces and memories can reside on one of the other chips or an additional chip. In yet another embodiment of the invention any portion of the MCU, the ASIC, the DSP, or the radio may can be integrated with the host system or implemented in software by executing instructions within a processor of the card, the host or an auxiliary system.

### General Matters

The present invention can be implemented in an i-BURST™ personal broadband access system. i-BURST™ is a trademark of ArrayComm, Inc. of San Jose, Calif. The i-BURST™ personal broadband access system provides a high-speed, wireless connection, for example to the Internet, for many wireless devices, such as portable computer systems (for example laptops), handheld devices (for example palmtops), digital cameras, game consoles, Internet appliances, etc. The i-BURST™ personal broadband access system provides speeds of more than 1 Mbps per user and up to 40 Mbps at any location, freedom to move, and an always-on connection.

In addition to i-BURST™ systems, embodiments of the present invention can be implemented in, low-mobility cellular and hot spot wireless communications systems. The present invention, while described in the context of i-BURST™ protocols is in no way restricted to using the i-BURST™ air interface or to TDMA systems, but may be utilized as part of any communication receiver, including CDMA systems using the IS-95 or WCDMA air interface, the GSM (Global System Mobile) air interface, the PHS (Personal Handyphone System defined by the Association of Radio Industries and Businesses ARIB, Japan) interface, IEEE 802.11, and WIFI, and also for wireless local loop (WLL) systems.

In the description above, for the purposes of explanation, numerous specific details are set forth in order to provide a thorough understanding of the present invention. It will be apparent, however, to one skilled in the art that the present invention may be practiced without some of these specific details. In other instances, well-known circuits, structures, devices, and techniques have been shown in block diagram form or without detail in order not to obscure the understanding of this description.

The present invention includes various steps. The steps of the present invention may be performed by hardware components, such as those shown in FIGS. 4, 5 and 6, or may be embodied in machine-executable instructions, which may be used to cause a general-purpose or special-purpose processor or logic circuits programmed with the instructions to perform the steps. Alternatively, the steps may be performed by a combination of hardware and software. The steps have been described as being performed by an adapter card of a user terminal. However, many of the steps described as being performed by the user terminal may be performed by the base station and vice versa. Furthermore, the invention is equally applicable to systems in which terminals communicate with each other without either one being designated as a base station, a user terminal, a remote terminal or a subscriber station. Thus, the present invention is equally applicable and useful in a peer-to-peer wireless network of communications devices using spatial processing. These devices may be cellular phones, PDA's, laptop computers, or any other wireless devices. Generally, since both the base stations and the terminals use radio waves, these communications devices of wireless communications networks may be generally referred to as radios.

The present invention may be provided as a computer program product, which may include a machine-readable medium having stored thereon instructions, which may be used to program a computer (or other electronic devices) to perform a process according to the present invention. The machine-readable medium may include, but is not limited to, floppy diskettes, optical disks, CD-ROMs, and magneto-optical disks, ROMs, RAMs, EPROMs, EEPROMs, magnet or optical cards, flash memory, or other type of media/machine-readable medium suitable for storing electronic instructions. Moreover, the present invention may also be downloaded as a computer program product, wherein the program may be transferred from a remote computer to a requesting computer by way of data signals embodied in a carrier wave or other propagation medium via a communication link (e.g., a modem or network connection).

Many of the methods are described in their most basic form, but steps can be added to or deleted from any of the methods and information can be added or subtracted from any of the described messages without departing from the basic scope of the present invention. It will be apparent to those skilled in the art that many further modifications and adaptations can be made. The particular embodiments are not provided to limit the invention but to illustrate it. The scope of the present invention is not to be determined by the specific examples provided above but only by the claims below.

It should also be appreciated that reference throughout this specification to “one embodiment” or “an embodiment” means that a particular feature may be included in the practice of the invention. Similarly, it should be appreciated that in the foregoing description of exemplary embodiments of the invention, various features of the invention are sometimes grouped together in a single embodiment, Figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the Detailed Description are hereby expressly incorporated into this Detailed Description, with each claim standing on its own as a separate embodiment of this invention.

What is claimed is:

1. An integrated circuit comprising:
an input buffer to store a digital test sequence;
a digital data modulator coupled to the input buffer to generate a modulated digital sample sequence using the test sequence;
a test buffer coupled to the modulator to receive and store a representation of the sample sequence; and
a test buffer output to enable the test buffer contents to be compared to a reference sequence.

2. The apparatus of claim 1, wherein the test buffer performs an operation to reduce the length of the sample sequence.

3. The apparatus of claim 2, wherein the test buffer performs a linear operation on the sample sequence to reduce the length of the sample sequence.

4. The apparatus of claim 3, wherein the test buffer comprises a linear feedback shift register (LFSR).

5. The apparatus of claim 4, wherein the LFSR has a length substantially less than the length of the sample sequence.

6. The apparatus of claim 1, further comprising a reference sequence buffer and a comparator coupled to the test buffer output and the reference sequence buffer to compare the contents of the test buffer and the reference sequence buffer and generate a success flag based on the comparison.

7. The apparatus of claim 1, further comprising a test pattern generator to provide the digital test sequence to the input buffer.

8. The apparatus of claim 7, wherein the test pattern generator comprises a pseudorandom number sequence generator.

9. The apparatus of claim 1, further comprising a test controller coupled to the modulator to initiate the modulation of the digital test sequence.

10. The apparatus of claim 9, further comprising a reference sequence buffer and a comparator coupled to the test buffer output and the reference sequence buffer, wherein the test controller is coupled to the comparator to initiate a comparison of the test buffer output to a reference sequence in the reference sequence buffer.

11. The apparatus of claim 9, further comprising a test pattern generator coupled to the test buffer input to provide the digital test sequence to the test buffer input and wherein the test controller is further coupled to the test pattern generator to cause the test pattern generator to provide the test pattern to the input buffer.

12. The apparatus of claim 9, wherein the test controller further comprises a start test input to receive a start test signal from an external device.

13. The apparatus of claim 10, wherein the test controller comprises a test input from an external device to initiate a test and the comparator comprises a test output to an external device to indicate the test results.

14. The apparatus of claim 9, wherein the digital data modulator includes a plurality of operations, and wherein the test controller commands the digital data modulator to cycle through each of the plurality of operations.

15. The apparatus of claim 14, wherein the operations comprise different combinations of encoding and symbol mapping.

16. The apparatus of claim 1, wherein the digital data modulator includes a plurality of operations, and wherein the digital data modulator has a start input to receive a start signal that includes a selection of one of the plurality of operations.

17. A method comprising:
storing a digital test sequence in an integrated circuit;
generating a modulated digital sample sequence using a digital data modulator of the integrated circuit based on the test sequence;
buffering a representation of the sample sequence on the integrated circuit; and
comparing the buffered representation to a reference sequence.

18. The method of claim 17, further comprising reducing the length of the sample sequence.

19. The method of claim 18, wherein reducing comprises performing a linear operation on the sample sequence to reduce the length of the sample sequence.

20. The method of claim 19, wherein reducing comprises generating a cyclic redundancy check code.

21. The method of claim 17, wherein comparing comprises comparing the buffered representation to the contents of a reference sequence buffer on the integrated circuit, the method further comprising generating a success flag based on the comparison.

22. The method of claim 17, further comprising generating the digital test sequence stored in the integrated circuit.

23. The method of claim 22, wherein generating the digital test sequence comprises generating a pseudorandom number sequence.

24. The method of claim 17, further comprising receiving test signal from an external device to initiate a test and generating a test output to an external device to indicate the test results.

25. The method of claim 17, wherein the digital data modulator includes a plurality of operations, and the method further comprising receiving a start signal that includes a selection of one of the plurality of operations.

26. A machine-readable medium having stored thereon data representing instructions which, when executed by a machine, cause the machine to perform operations comprising:
storing a digital test sequence in an integrated circuit;
generating a modulated digital sample sequence using a digital data modulator of the integrated circuit based on the test sequence;
buffering a representation of the sample sequence on the integrated circuit; and
comparing the buffered representation to a reference sequence.

27. The medium of claim 26, wherein the instruction further comprise instructions which, when executed by the machine, cause the machine to perform further operations comprising reducing the length of the sample sequence.

28. The medium of claim 27, wherein the instructions for reducing comprise instructions which, when executed by the machine, cause the machine to perform further operations generating a cyclic redundancy check code.

29. The medium of claim 26, wherein the instructions for comparing comprise instructions which, when executed by the machine, cause the machine to perform further operations comprising comparing the buffered representation to the contents of a reference sequence buffer on the integrated circuit, the instructions further comprising instructions which, when executed by the machine, cause the machine to perform further operations comprising generating a success flag based on the comparison.

30. The medium of claim 26, further comprising instructions which, when executed by the machine, cause the machine to perform further operations comprising receiving test signal from an external device to initiate a test and generating a test output to an external device to indicate the test results.

31. The medium of claim 26, wherein the digital data modulator includes a plurality of operations, and the instructions further comprising instructions which, when executed by the machine, cause the machine to perform further operations comprising receiving a start signal that includes a selection of one of the plurality of operations.

32. An integrated circuit comprising:
an input buffer to store a digital test sequence;
a digital processor coupled to the input buffer that generates a digital output sequence;
a test buffer coupled to the modulator to receive the output sequence, to perform an operation to reduce the size of the output sequence, and to store the reduced output sequence; and
a test buffer output to enable the test buffer contents to be compared to a reference sequence.

33. The apparatus of claim 32, wherein the test buffer performs a linear operation on the output sequence to reduce the length of the sample sequence.

34. The apparatus of claim 33, wherein the test buffer comprises a linear feedback shift register (LFSR).

35. The apparatus of claim 34, wherein the LFSR has a length substantially less than the length of the output sequence.

36. The apparatus of claim 32, further comprising a reference sequence buffer and a comparator coupled to the test buffer output and the reference sequence buffer to compare the contents of the test buffer and the reference sequence buffer and generate a success flag based on the comparison.

37. The apparatus of claim 32, further comprising a test pattern generator to provide a test pattern to the input buffer.

38. The apparatus of claim 32, further comprising a pseudorandom number sequence generator to provide a test pattern to the input buffer.

39. The apparatus of claim 32, further comprising a test controller coupled to the digital processor to initiate the modulation of the test sequence.

40. The apparatus of claim 39, further comprising a reference sequence buffer and a comparator coupled to the test buffer output and the reference sequence buffer, wherein the test controller is coupled to the comparator to initiate a comparison of the test buffer output to a reference sequence in the reference sequence buffer.

41. The apparatus of claim 39, wherein the test controller comprises a start test input from an external device to initiate a test and a test output to an external device to indicate the test results.

42. The apparatus of claim 39, wherein the digital processor is capable of performing a plurality of operations, and wherein the test controller commands the digital processor to cycle through a plurality of operations performed on one or more test sequences.

43. A method comprising:
storing a digital test sequence;
generating a digital output sequence based on the stored test sequence using a digital processor;
performing an operation to reduce the size of the output sequence;
storing the reduced output sequence; and
comparing the reduced output sequence to a reference sequence.

44. The method of claim 43, wherein performing comprises performing a linear operation on the output sequence to reduce the length of the sample sequence.

45. The method of claim 44, wherein the linear operation comprises generating a cyclic redundancy check code.

46. The method of claim 46, further comprising generating a digital test sequence before storing the digital test sequence.

47. The method of claim 46, wherein generating comprises generating a pseudorandom number sequence.

48. The method of claim 43, further comprising receiving a start test input from an external device to initiate a test generating a test output to an external device to indicate the test results.

49. A machine-readable medium having stored thereon data representing instructions which, when executed by a machine, cause the machine to perform operations comprising:
storing a digital test sequence;
generating a digital output sequence based on the stored test sequence using a digital processor;
performing an operation to reduce the size of the output sequence;
storing the reduced output sequence; and
comparing the reduced output sequence to a reference sequence.

50. The medium of claim 49, wherein the instructions for performing comprise instructions which, when executed by the machine, cause the machine to perform further operations comprising performing a linear operation on the output sequence to reduce the length of the sample sequence.

51. The medium of claim 50, wherein the linear operation comprises generating a cyclic redundancy check code.

52. The medium of claim 49, further comprising instructions which, when executed by the machine, cause the machine to perform further operations comprising generating a digital test sequence before storing the digital test sequence.

53. The medium of claim 52, wherein the instructions for generating comprise instructions which, when executed by the machine, cause the machine to perform further operations comprising generating a pseudorandom number sequence.

54. The medium of claim 49, further comprising instructions which, when executed by the machine, cause the machine to perform further operations comprising receiving a start test input from an external device to initiate a test generating a test output to an external device to indicate the test results.

55. An interchangeable computer adapter card comprising:
a master control unit to control operations performed on the card;
a radio section to transmit and receive radio signals to and from the card;
a card interface to communicate data between the card and a computer host;
an input buffer to store a digital test sequence to be transmitted;
a digital data modulator coupled to the input buffer to generate a modulated digital sample sequence using the test sequence;
a test buffer coupled to the modulator to receive and store a representation of the sample sequence; and
a test buffer output to enable the test buffer contents to be compared to a reference sequence.

56. The apparatus of claim 55, wherein the test buffer performs an operation to reduce the length of the sample sequence.

57. The apparatus of claim 56, wherein the test buffer performs a linear operation on the sample sequence to reduce the length of the sample sequence.

58. The apparatus of claim 55, further comprising:
a reference sequence buffer;
a comparator coupled to the test buffer output and the reference sequence buffer; and
a test controller coupled to the modulator to initiate the modulation of the digital test sequence, wherein the test controller is coupled to the comparator to initiate a comparison of the test buffer output to a reference sequence in the reference sequence buffer.

59. The apparatus of claim 58, wherein the test controller further comprises a start test input from the master control unit to receive a start test signal from the master control unit, and a test output to the master control unit to indicate the test results.

60. The apparatus of claim 59, wherein the digital data modulator includes a plurality of operations, and wherein the test controller has an input from the master control unit to receive a start signal that includes a selection of one of the plurality of operations.
